(19) United States
(12) Patent Application Publication
(10) Pub. No.: US 2010/0320591 A1
(43) Pub. Date: Dec. 23, 2010

(54) INTEGRATED CIRCUIT PACKAGING SYSTEM WITH CONTACT PADS AND METHOD OF MANUFACTURE THEREOF

(76) Inventors: Zigmund Ramirez Camacho, Singapore (SG); Lionel Chien Hui Tay, Singapore (SG); Henry Descalzo Bathan, Singapore (SG); Frederick Rodriguez Dahilig, Singapore (SG)

Correspondence Address: LAW OFFICES OF MIKIO ISHIMARU, 333 W. EL CAMINO REAL, SUITE 330, SUNNYVALE, CA, 94087, US

(21) Appl. No.: 12/488,412

(22) Filed: Jun. 19, 2009

(51) Int. Cl. H01L 23/52; H01L 21/56

(52) U.S. Cl. 257/692; 438/124; 257/723; 257/738; 257/E23.141; 257/E21.502; 257/E21.506

(57) ABSTRACT

A method of manufacture of an integrated circuit packaging system includes: attaching contact pads to a base structure; connecting a base die to the base structure; connecting a supporting die over the base die by conductive balls to the contact pads on two sides of the base die; encapsulating the contact pads, the base die, the supporting die, and the conductive balls; and removing the base structure.

### CROSS-REFERENCE TO RELATED APPLICATION(S)

The present application contains subject matter related to co-pending U.S. patent application Ser. No. 12/235,000 filed Sep. 22, 2008. The related application is assigned to STATS ChipPAC Ltd. and the subject matter thereof is incorporated herein by reference thereto.

### TECHNICAL FIELD

The present invention relates generally to an integrated circuit packaging system, and more particularly to an integrated circuit packaging system with contact pads.

### BACKGROUND ART

In the electronics industry, the tendency has been to reduce the size of electronic devices such as camcorders and portable telephones while increasing performance and speed. Integrated circuit packages for complex systems typically are comprised of multiple interconnected integrated circuit chips. The integrated circuit chips usually are made from a semiconductor material such as silicon or gallium arsenide. The integrated circuit chips may be mounted in packages that are then mounted on printed wiring boards.

Typically, the packages on which the integrated semiconductor chips are mounted include a substrate or other chip-mounting device. Substrates are parts that provide a package with mechanical base support and a form of electrical interface that would allow the external world to access the devices housed within the package.

Semiconductor chips may be attached to the substrate using adhesive or any other techniques for attaching such chips to a substrate which are commonly known to those skilled in the art. The power, ground and/or signal sites on the chip may then be electrically connected to individual leads on the substrate through techniques such as wire bonding.

One example of such a substrate is a leadframe. A leadframe typically includes at least an area on which an integrated circuit chip is mounted and multiple power, ground, and/or signal leads to which power, ground, and/or signal sites of the integrated semiconductor die are electronically attached. The area on which the integrated circuit is mounted is typically called a die pad. The multiple leads typically form the outer frame of the leadframe. The die pad is typically connected to the outer frame leads by tiebars so that the whole leadframe is a single integral piece of metal.

Conventionally, one or more semiconductor dies are manufactured and are mounted on a main substrate. Then, the different parts of the assembly are encapsulated in a mold compound. A singulation process is utilized to realize individually separated semiconductor packages.

In typical leadframe packages, the semiconductor die mounted is smaller than or of the same size of the die pad. In such a configuration, the surrounding leads occupy space where there is no functional semiconductor device. Therefore the density of semiconductor devices on the leadframe is limited. The modern trend of the semiconductor manufacturing and packaging is to increase the device density on the leadframe. Therefore such wasted space in the typical leadframe design presents a problem.

Furthermore, building semiconductor packages on leadframe entails high cost and high complexity. As the complexity of the semiconductor package increases, the design of the leadframes becomes more complicated, and hence increases its cost. The process of manufacturing leadframe semiconductor packages also becomes more and more complex as the number of semiconductor chip integrated within a single package increases and the level of functional complexity also increases. Increased complexity inevitably imposes risks of reliability.

Thus, a need still remains for accommodating the modern trend of semiconductor manufacturing and packaging, reducing the package footprint increasing the packaging density, reducing packaging cost, reducing process complexity, and increasing reliability of semiconductor packages. In view of the ever-increasing commercial competitive pressures, along with growing consumer expectations and the diminishing opportunities for meaningful product differentiation in the marketplace, it is critical that answers be found for these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system including: attaching contact pads to a base structure; connecting a base die to the base structure; connecting a supporting die over the base die by conductive balls to the contact pads on two sides of the base die; encapsulating the contact pads, the base die, the supporting die, and the conductive balls; and removing the base structure.

The present invention provides an integrated circuit packaging system including: contact pads; a base die connected to the contact pads; a supporting die supported over the base die by conductive balls to the contact pads on two sides of the base die; and an encapsulant encapsulating the contact pads, the base die, the supporting die, and the conductive balls.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIG. 1 is a cross-sectional view of a semiconductor packaging system of a first embodiment of the present invention after a stage of singulation.

FIG. 2 is a cross-sectional view of a semiconductor packaging system of a second embodiment of the present invention after a stage of singulation.

FIG. 3 is a cross-sectional view of a semiconductor packaging system of a third embodiment of the present invention after a stage of singulation.

FIG. 4 is a cross-sectional view of a semiconductor packaging system of a fourth embodiment of the present invention after a stage of singulation.

FIG. 5 is a cross-sectional view of a semiconductor packaging system of a fifth embodiment of the present invention after a stage of singulation.

FIG. 6 is a cross-sectional view of a semiconductor packaging system of a sixth embodiment of the present invention after a stage of singulation.

FIG. 7 is a cross-sectional view of a semiconductor packaging system of a seventh embodiment of the present invention after a stage of singulation.

FIG. 8 is a cross-sectional view of a semiconductor packaging system of an eighth embodiment of the present invention after a stage of singulation.

FIG. 9 is a cross-sectional view of a semiconductor packaging system of a ninth embodiment of the present invention after a stage of singulation.

FIG. 10 is a cross-sectional view of a semiconductor packaging system of a tenth embodiment of the present invention after a stage of singulation.

FIG. 11 is a cross-sectional view of a semiconductor packaging system of the first embodiment of the present invention after a starting stage of the process.

FIG. 12 is a cross-sectional view similar to FIG. 11 of a semiconductor packaging system of the first embodiment of the present invention after a base die attach stage of the process.

FIG. 13 is a cross-sectional view similar to FIG. 12 of a semiconductor packaging system of the first embodiment of the present invention after a supporting die attach stage of the process.

FIG. 14 is a cross-sectional view similar to FIG. 13 of a semiconductor packaging system of the first embodiment of the present invention after a top device attach and wire bonding stage of the process.

FIG. 15 is a cross-sectional view similar to FIG. 14 of a semiconductor packaging system of the first embodiment of the present invention after an encapsulation stage of the process.

FIG. 16 is a cross-sectional view similar to FIG. 15 of a semiconductor packaging system of the first embodiment of the present invention after a base structure removal and singulation stage of the process.

FIG. 17 is a flow chart of a method of manufacture of an integrated circuit packaging system in a further embodiment of the present invention.

### BEST MODE FOR CARRYING OUT THE INVENTION

The following embodiments are described in sufficient details to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings generally show similar orientations for ease of description, this depiction in the FIGs. is arbitrary for the most part. Generally, the invention can be operated in any orientation.

Where multiple embodiments are disclosed and described having some features in common, for clarity and ease of illustration, description, and comprehension thereof, similar and like features one to another will ordinarily be described with similar reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the semiconductor substrate, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the drawings. The term “on” means that there is direct contact among elements.

The term “processing” as used herein includes deposition of material or photoresist, patterning, exposure, development, etching, cleaning, and/or removal of the material or photoresist as required in forming a described structure.

The term “connecting” as used herein encompasses both “attaching” and “electrically connecting”.

The term “coplanar” is defined as being in the same plane or flat. With regard to an unfinished leadframe the term means that the unfinished leadframe is in one plane and flat as contrasted with having different heights.

Referring now to FIG. 1, therein is shown a cross-sectional view of a semiconductor packaging system of a first embodiment of the present invention after a stage of singulation.

A semiconductor package 100 is shown to have a base die 102 attached to a bumped die attach pad 104 through a die adhesive 106. The base die 102 has a base die pad 108. A bumped contact pad 110 is shown to be coplanar to the bumped die attach pad 104. Both the bumped contact pad 110 and the bumped die attach pad 104 could be plated with a layer of metal.

A supporting die 112 is shown to have a supporting die center pad 114. A further conductive ball 116 connects the base die pad 108 of the base die 102 to the supporting die center pad 114 of the supporting die 112. The supporting die 112 also has a supporting die side pad 118. A conductive ball 120 connects the supporting die side pad 118 of the supporting die 112 to the bumped contact pad 110. The conductive ball 120 could be a solder ball.

In this embodiment of the present invention, the supporting die 112 is said to have a flip chip configuration because the supporting die center pad 114 and the supporting die side pad 118 are at the bottom surface of the supporting die 112.

A top device 122 is attached to the supporting die 112 through an interconnecting adhesive layer 124. The top device 122 has a top device pad 126. A bonding wire 128 connects the top device pad 126 of the top device 122 to the bumped contact pad 110. The top device 122 can be either a die or an intermediate substrate.

The base die 102, the die adhesive 106, the supporting die 112, the further conductive ball 116, the conductive ball 120, the top device 122, the interconnecting adhesive layer 124, and the bonding wire 128 are encapsulated in an encapsulant 130.

The semiconductor package 100 houses several semiconductor chips such as the base die 102, the supporting die 112, and the top device 122. Each semiconductor chip can assume different functionalities. It is found that such a configuration enhances the functionalities integration of the semiconductor package 100.

The bumped die attach pad 104 and the bumped contact pad 110 reduce the overall height of the package due to their concave shape. It has been discovered that such configuration saves spaces for the semiconductor package and increase packaging density.

The process of building semiconductor package 100 is accomplished without using the conventional a leadframe structure. It has been discovered that such a process is less costly than using the conventional leadframe structure. It has also been discovered that such a process provides a simpler process for semiconductor chip integration.

The semiconductor package 100 presents an integrated device structure with both the conductive ball 120 and the bonding wire 128 as interconnections. It has been discovered that such a device structure improves reliability of the semiconductor package.

Thus, it has been discovered that the integrated circuit packaging system of the present invention furnishes important and heretofore unknown and unavailable solutions, capabilities, and functional aspects for increasing functionality integration, increasing packaging density, saving space, reducing processing and manufacturing complexity, reducing cost, and enhancing reliability.

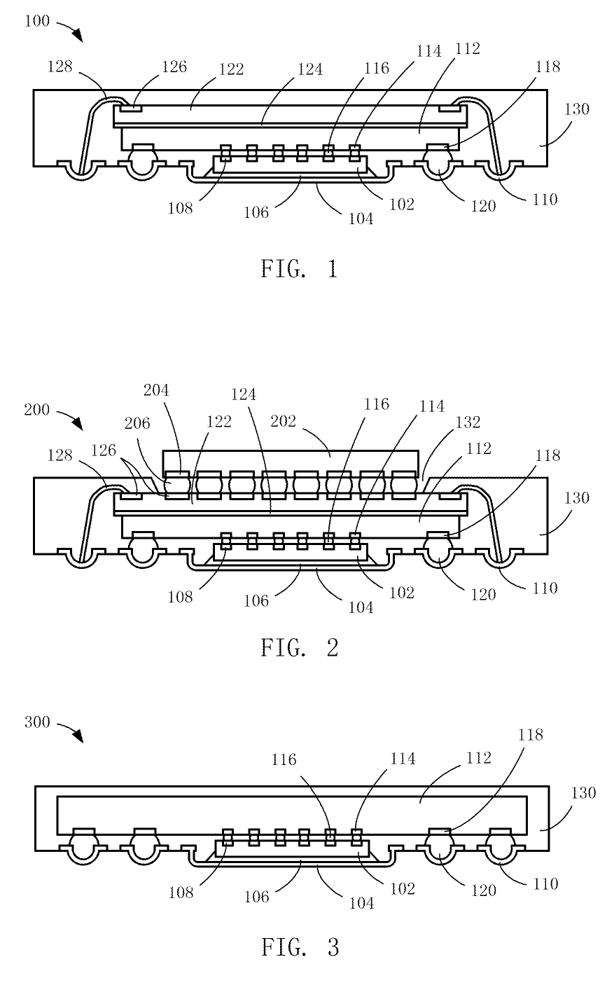

Referring now to FIG. 2, therein is shown a cross-sectional view of a semiconductor packaging system of a second embodiment of the present invention after a stage of singulation.

A semiconductor package 200 is shown to have the base die 102 attached to the bumped die attach pad 104 through the die adhesive 106. The base die 102 has the base die pad 108. The bumped contact pad 110 is shown to be coplanar to the bumped die attach pad 104.

The supporting die 112 is shown to have the supporting die center pad 114. The further conductive ball 116 connects the base die pad 108 of the base die 102 to the supporting die center pad 114 of the supporting die 112. The supporting die 112 also has the supporting die side pad 118. The conductive ball 120 connects the supporting die side pad 118 of the supporting die 112 to the bumped contact pad 110.

In this embodiment of the present invention, the supporting die 112 is said to have a flip chip configuration because the supporting die center pad 114 and the supporting die side pad 118 are at the bottom surface of the supporting die 112.

The top device 122 is attached to the supporting die 112 through the interconnecting adhesive layer 124. The top device 122 has the top device pad 126. The bonding wire 128 connects the top device pad 126 of the top device 122 to the bumped contact pad 110.

The base die 102, the die adhesive 106, the supporting die 112, the further conductive ball 116, the conductive ball 120, the top device 122, the interconnecting adhesive layer 124, and the bonding wire 128 are encapsulated in the encapsulant 130.

The encapsulant 130 has an encapsulant opening 132. The encapsulant opening 132 exposes the top surface of the top device 122 as well as some of the top device pad 126.

A further die 202 is shown to have a further die pad 204. A top conductive ball 206 connects the further die pad 204 of the further die 202 to the top device pad 126 of the top device 122. The top conductive ball 206 could be a solder ball.

In this embodiment of the present invention, the further die 202 is said to have a flip chip configuration because the further die pad 204 is at the bottom surface of the further die 202.

Compared to semiconductor package 100 of FIG. 1, semiconductor package 200 has an additional semiconductor chip, the further die 202. It has been discovered that such a configuration further improves the functionality integration of the semiconductor package.

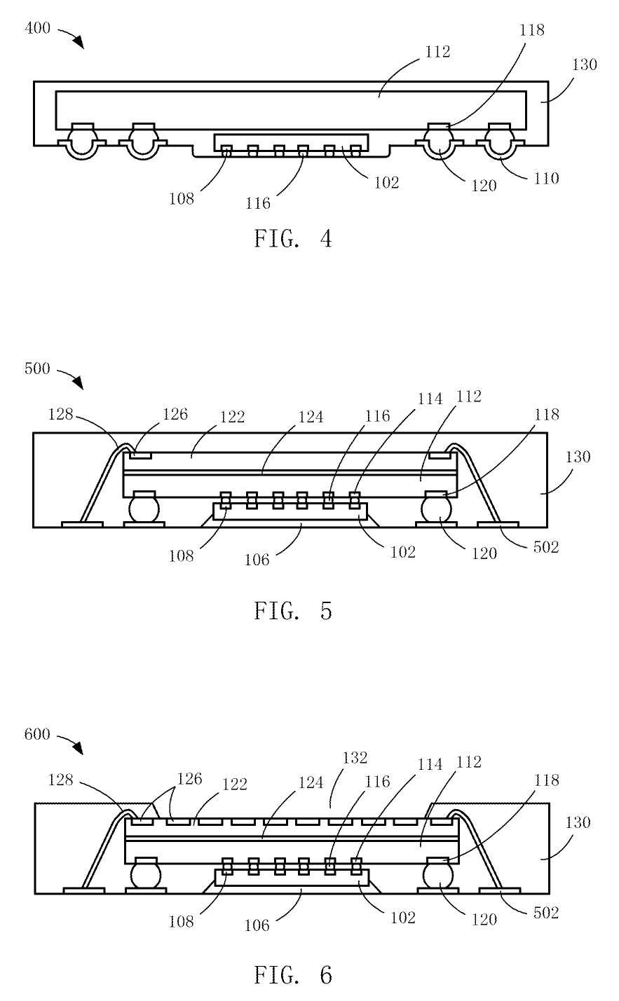

Referring now to FIG. 3, therein is shown a cross-sectional view of a semiconductor packaging system of a third embodiment of the present invention after a stage of singulation.

A semiconductor package 300 is shown to have the base die 102 attached to the bumped die attach pad 104 through the die adhesive 106. The base die 102 has the base die pad 108. The bumped contact pad 110 is shown to be coplanar to the bumped die attach pad 104.

The supporting die 112 is shown to have the supporting die center pad 114. The further conductive ball 116 connects the base die pad 108 of the base die 102 to the supporting die center pad 114 of the supporting die 112. The supporting die 112 also has the supporting die side pad 118. The conductive ball 120 connects the supporting die side pad 118 of the supporting die 112 to the bumped contact pad 110.

In this embodiment of the present invention, the supporting die 112 is said to have a flip chip configuration because the supporting die center pad 114 and the supporting die side pad 118 are at the bottom surface of the supporting die 112.

The base die 102, the die adhesive 106, the supporting die 112, the further conductive ball 116, and the conductive ball 120 are encapsulated in the encapsulant 130.

In this embodiment of the present invention, the supporting die 112 can be a wafer-level chip scale packaging (WLCSP) chip. It has been discovered that such a configuration facilitate simple and reliable integration of semiconductor packages.

Referring now to FIG. 4, therein is shown a cross-sectional view of a semiconductor packaging system of a fourth embodiment of the present invention after a stage of singulation.

A semiconductor package 400 is shown to have the base die 102. The base die 102 has the base die pad 108. The bumped contact pad 110 is also shown.

Compared to the semiconductor package 100 of FIG. 1, the semiconductor package 400 lacks the bumped die attach pad 104. In this embodiment of the present invention, the base die 102 is said to have a flip chip configuration because the base die pad 108 is at the bottom surface of the base die 102. Furthermore, the further conductive ball 116 is facing down while still attached to the base die pad 108.

The supporting die 112 is shown to have the supporting die side pad 118. The conductive ball 120 connects the supporting die side pad 118 of the supporting die 112 to the bumped contact pad 110.

In this embodiment of the present invention, the supporting die 112 is said to have a flip chip configuration because the supporting die side pad 118 is at the bottom surface of the supporting die 112.

The base die 102, the supporting die 112, the further conductive ball 116, and the conductive ball 120 are encapsulated in the encapsulant 130. The bottom of the further conductive ball 116 is exposed and is not encapsulated by the encapsulant 130.

In this embodiment of the present invention, the supporting die 112 can be a WLCSP chip. It has been discovered that such a configuration facilitate simple and reliable integration of semiconductor packages.

Referring now to FIG. 5, therein is shown a cross-sectional view of a semiconductor packaging system of a fifth embodiment of the present invention after a stage of singulation.

A semiconductor package 500 is shown to have the base die 102 attached to the die adhesive 106. The base die 102 has the base die pad 108. A contact pad 502 is shown to be coplanar to the bottom surface of the die adhesive 106.

The supporting die 112 is shown to have the supporting die center pad 114. The further conductive ball 116 connects the base die pad 108 of the base die 102 to the supporting die center pad 114 of the supporting die 112. The supporting die 112 also has the supporting die side pad 118. The conductive ball 120 connects the supporting die side pad 118 of the supporting die 112 to the contact pad 502.

In this embodiment of the present invention, the supporting die 112 is said to have a flip chip configuration because the supporting die center pad 114 and the supporting die side pad 118 are at the bottom surface of the supporting die 112.

The top device 122 is attached to the supporting die 112 through the interconnecting adhesive layer 124. The top device 122 has the top device pad 126. The bonding wire 128 connects the top device pad 126 of the top device 122 to the contact pad 502.

The base die 102, the die adhesive 106, the supporting die 112, the further conductive ball 116, the conductive ball 120, the top device 122, the interconnecting adhesive layer 124, and the bonding wire 128 are encapsulated in the encapsulant 130.

Referring now to FIG. 6, therein is shown a cross-sectional view of a semiconductor packaging system of a sixth embodiment of the present invention after a stage of singulation.

A semiconductor package 600 is shown to have the base die 102 attached to the die adhesive 106. The base die 102 has the base die pad 108. The contact pad 502 is shown to be coplanar to the bottom surface of the die adhesive 106.

The supporting die 112 is shown to have the supporting die center pad 114. The further conductive ball 116 connects the base die pad 108 of the base die 102 to the supporting die center pad 114 of the supporting die 112. The supporting die 112 also has the supporting die side pad 118. The conductive ball 120 connects the supporting die side pad 118 of the supporting die 112 to the contact pad 502.

In this embodiment of the present invention, the supporting die 112 is said to have a flip chip configuration because the supporting die center pad 114 and the supporting die side pad 118 are at the bottom surface of the supporting die 112.

The top device 122 is attached to the supporting die 112 through the interconnecting adhesive layer 124. The top device 122 has the top device pad 126. The bonding wire 128 connects the top device pad 126 of the top device 122 to the contact pad 502.

The base die 102, the die adhesive 106, the supporting die 112, the further conductive ball 116, the conductive ball 120, the top device 122, the interconnecting adhesive layer 124, and the bonding wire 128 are encapsulated in the encapsulant 130.

The encapsulant 130 has the encapsulant opening 132. The encapsulant opening 132 exposes the top surface of the top device 122 as well as some of the top device pad 126.

The encapsulant opening 132 and the exposed top surface of the top device 122 enable further device integration through attaching additional semiconductor chips to the top device 122.

Referring now to FIG. 7, therein is shown a cross-sectional view of a semiconductor packaging system of a seventh embodiment of the present invention after a stage of singulation.

A semiconductor package 700 is shown to have the base die 102 attached to the die adhesive 106. The base die 102 has the base die pad 108. The contact pad 502 is shown to be coplanar to the bottom surface of the die adhesive 106.

The supporting die 112 is shown to have the supporting die center pad 114. The further conductive ball 116 connects the base die pad 108 of the base die 102 to the supporting die center pad 114 of the supporting die 112. The supporting die 112 also has the supporting die side pad 118. The conductive ball 120 connects the supporting die side pad 118 of the supporting die 112 to the contact pad 502.

In this embodiment of the present invention, the supporting die 112 is said to have a flip chip configuration because the supporting die center pad 114 and the supporting die side pad 118 are at the bottom surface of the supporting die 112.

The top device 122 is attached to the supporting die 112 through the interconnecting adhesive layer 124. The top device 122 has the top device pad 126. The bonding wire 128 connects the top device pad 126 of the top device 122 to the contact pad 502.

The further die 202 is shown to have the further die pad 204. The top conductive ball 206 connects the further die pad 204 of the further die 202 to the top device pad 126 of the top device 122.

The base die 102, the die adhesive 106, the supporting die 112, the further conductive ball 116, the conductive ball 120, the top device 122, the interconnecting adhesive layer 124, the bonding wire 128, a portion of the further die 202, and the top conductive ball 206 are encapsulated in the encapsulant 130. The top surface of the further die 202 is exposed and is not encapsulated.

In this embodiment of the present invention, the further die 202 is said to have a flip chip configuration because the further die pad 204 is at the bottom surface of the further die 202.

It has been discovered that the exposed top surface of the further die 202 enhances thermal dissipation of the semiconductor package and hence improves the reliability of the semiconductor package.

Referring now to FIG. 8, therein is shown a cross-sectional view of a semiconductor packaging system of an eighth embodiment of the present invention after a stage of singulation.

A semiconductor package 800 is shown to have the base die 102 attached to the die adhesive 106. The base die 102 has the base die pad 108. A contact pad 502 is shown to be coplanar to the bottom surface of the die adhesive 106.

The supporting die 112 is shown to have the supporting die center pad 114. The further conductive ball 116 connects the base die pad 108 of the base die 102 to the supporting die center pad 114 of the supporting die 112. The supporting die 112 also has the supporting die side pad 118. The conductive ball 120 connects the supporting die side pad 118 of the supporting die 112 to the contact pad 502.

In this embodiment of the present invention, the supporting die 112 is said to have a flip chip configuration because the supporting die center pad 114 and the supporting die side pad 118 are at the bottom surface of the supporting die 112.

The base die 102, the die adhesive 106, the supporting die 112, the further conductive ball 116, and the conductive ball 120 are encapsulated in the encapsulant 130.

In this embodiment of the present invention, the supporting die 112 can be a WLCSP chip. It has been discovered that such a configuration facilitate simple and reliable integration of semiconductor packages.

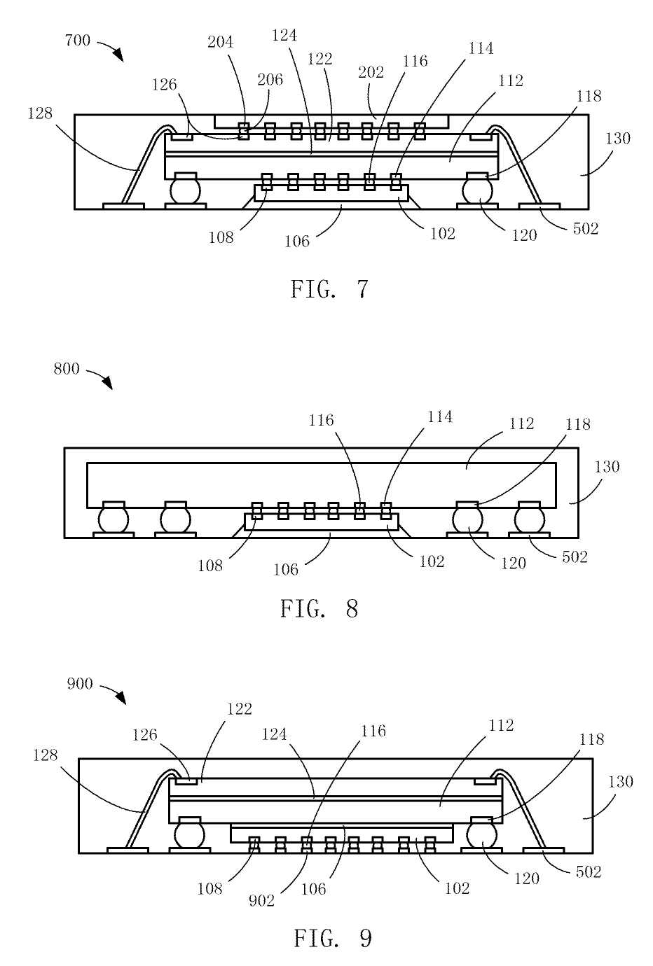

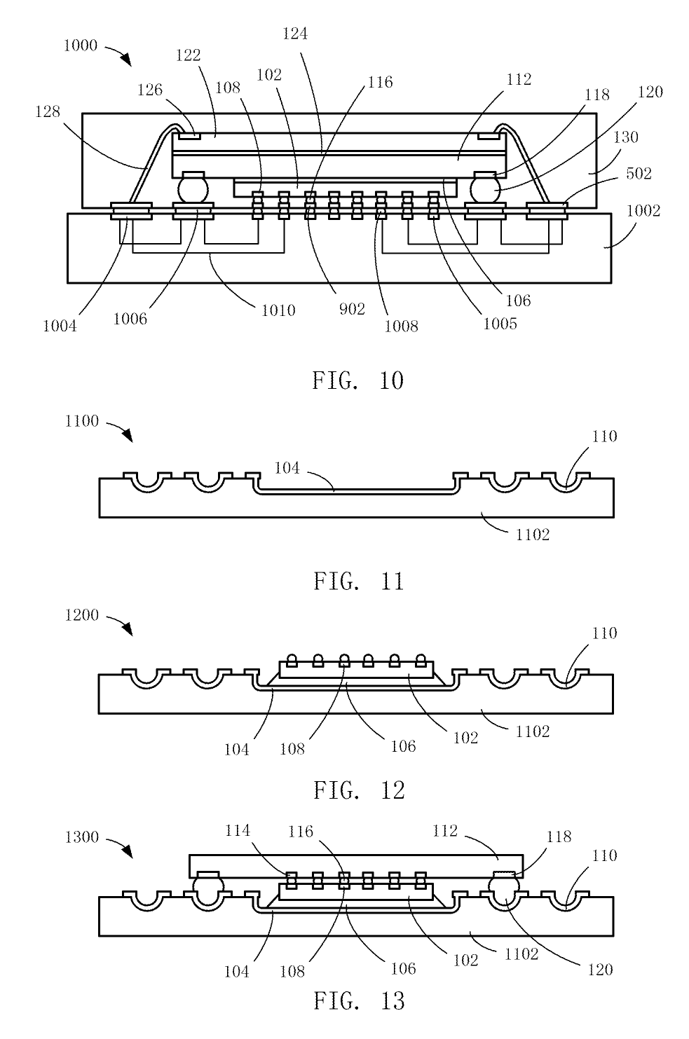

Referring now to FIG. 9, therein is shown a cross-sectional view of a semiconductor packaging system of a ninth embodiment of the present invention after a stage of singulation.

A semiconductor package 900 is shown to have the base die 102 attached to the supporting die 112 through the die adhesive 106. The base die 102 has the base die pad 108. The further conductive ball 116 connects the base die pad 108 to a base die center flat pad 902. The contact pad 502 is shown to be coplanar to the base die center flat pad 902.

The supporting die 112 is shown to have the supporting die side pad 118. The conductive ball 120 connects the supporting die side pad 118 of the supporting die 112 to the contact pad 502.

The top device 122 is attached to the supporting die 112 through the interconnecting adhesive layer 124. The top device 122 has the top device pad 126. The bonding wire 128 connects the top device pad 126 of the top device 122 to the contact pad 502.

The base die 102, the die adhesive 106, the base die center flat pad 902, the supporting die 112, the further conductive ball 116, the conductive ball 120, the top device 122, the interconnecting adhesive layer 124, and the bonding wire 128 are encapsulated in the encapsulant 130. The bottom surface of the base die center flat pad 902 and the bottom surface of the contact pad 502 are exposed.

Referring now to FIG. 10, therein is shown a cross-sectional view of a semiconductor packaging system of a tenth embodiment of the present invention after a stage of singulation.

A semiconductor package 1000 is shown. The base die 102 is attached to the supporting die 112 through the die adhesive 106. The base die 102 has the base die pad 108. The further conductive ball 116 connects the base die pad 108 to the base die center flat pad 902. The contact pad 502 is shown to be coplanar to the base die center flat pad 902.

The supporting die 112 is shown to have the supporting die side pad 118. The conductive ball 120 connects the supporting die side pad 118 of the supporting die 112 to the contact pad 502.

The top device 122 is attached to the supporting die 112 through the interconnecting adhesive layer 124. The top device 122 has the top device pad 126. The bonding wire 128 connects the top device pad 126 of the top device 122 to the contact pad 502.

The base die 102, the die adhesive 106, the base die center flat pad 902, the supporting die 112, the further conductive ball 116, the conductive ball 120, the top device 122, the interconnecting adhesive layer 124, and the bonding wire 128 are encapsulated in the encapsulant 130.

A printed circuit board 1002 is also shown. The printed circuit board 1002 has a printed circuit board side plate 1004 and a printed circuit board center plate 1005. A printed circuit board side connecting layer 1006 connects the contact pad 502 to the printed circuit board center plate 1004. A printed circuit board center connecting layer 1008 connects the base die center flat pad 902 to the printed circuit board center plate 1005. A printed circuit board electrical connection 1010 is also established between the printed circuit board side plate 1004 and the printed circuit board center plate 1005.

It has been discovered that this embodiment of the present invention facilitate simple and easy routing between the functional chips encapsulated in the encapsulant 130 and the printed circuit board 1002.

Referring now to FIG. 11, therein is shown a cross-sectional view of a semiconductor packaging system of the first embodiment of the present invention after a starting stage of the process.

A semiconductor package 1100 is shown to have a base structure 1102. The base structure 1102 is patterned and has the bumped die attach pad 104 and the bumped contact pad 110. The base structure 1102 could be a copper sheet. The bumped die attach pad 104 and the bumped contact pad 110 could be plated with a layer of metal.

In prior art semiconductor packages, the base structure 1102 is not present and instead, a bismaleimide triazine (BT) laminated substrate is often used. It has been discovered that the use of the base structure 1102 is 10 times less costly than the BT laminated substrate, hence reduces the cost of the manufacturing of the semiconductor package substantially.

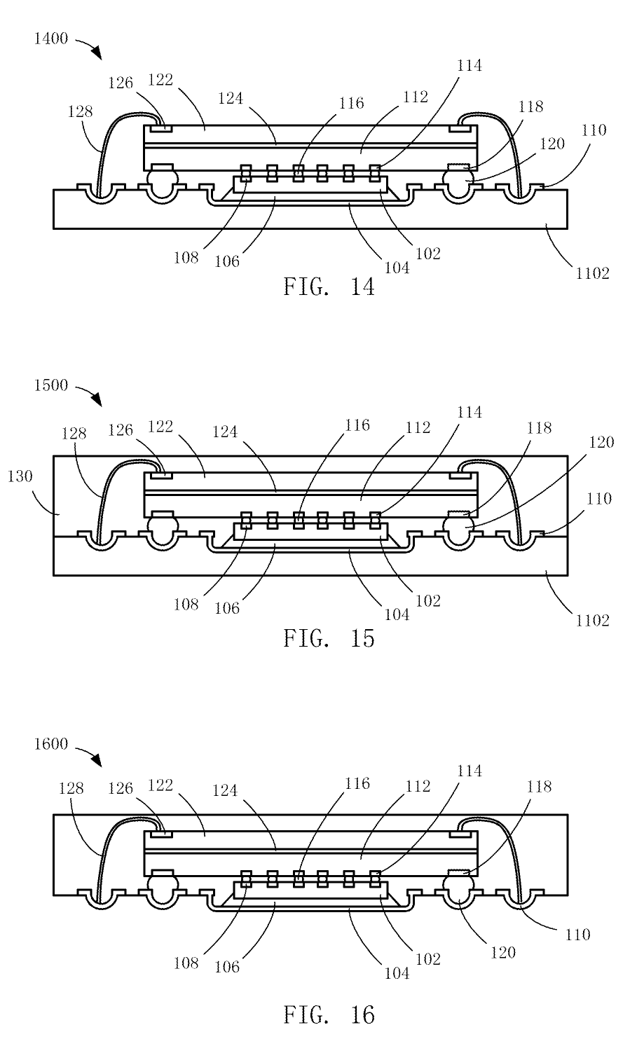

Referring now to FIG. 12, therein is shown a cross-sectional view similar to FIG. 11 of a semiconductor packaging system of the first embodiment of the present invention after a base die attach stage of the process.

The base die 102 is attached to the bumped die attach pad 104 using the die adhesive 106. The base die 102 has the base die pad 108.

Referring now to FIG. 13, therein is shown a cross-sectional view similar to FIG. 12 of a semiconductor packaging system of the first embodiment of the present invention after a supporting die attach stage of the process.

The supporting die 112 is added and is shown to have the supporting die center pad 114 and the supporting die side pad 118. The further conductive ball 116 connects the supporting die center pad 114 of the supporting die to the base die pad 108 of the base die 102. The conductive ball 120 connects the supporting die side pad 118 of the supporting die 112 to the bumped contact pad 110.

Referring now to FIG. 14, therein is shown a cross-sectional view similar to FIG. 13 of a semiconductor packaging system of the first embodiment of the present invention after a top device attach and wire bonding stage of the process.

The top device 122 is then attached to the supporting die 112 through the interconnecting adhesive layer 124. The top device 122 has the top device pad 126. The bonding wire connects the top device pad 126 to the bumped contact pad 110.

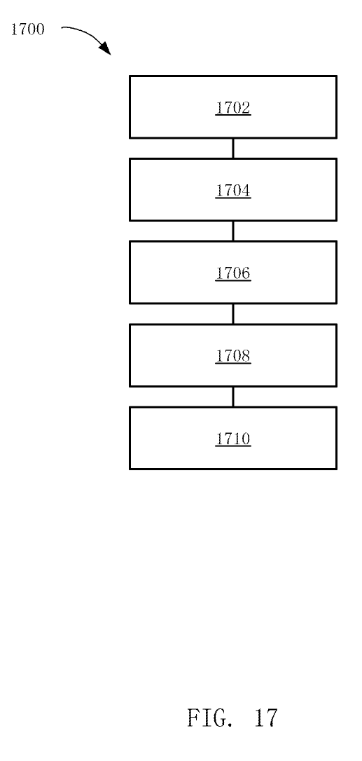

Referring now to FIG. 15, therein is shown a cross-sectional view similar to FIG. 14 of a semiconductor packaging system of the first embodiment of the present invention after an encapsulation stage of the process.

The base die 102, the die adhesive 106, the supporting die 112, the further conductive ball 116, the conductive ball 120, the top device 122, the interconnecting adhesive layer 124, and the bonding wire 128 are then encapsulated in the encapsulant 130.

Referring now to FIG. 16, therein is shown a cross-sectional view similar to FIG. 15 of a semiconductor packaging system of the first embodiment of the present invention after a base structure removal and singulation stage of the process.

The base structure 1102 in FIG. 15 is removed. The process of the removal could be by strip etch or other process. Then the encapsulant 130 is singulated to form a separate finished semiconductor package.

Referring now to FIG. 17, therein is shown a flow chart of a method 1700 of manufacture of an integrated circuit packaging system in a further embodiment of the present invention. The method 1700 includes: attaching contact pads to a base structure in a block 1702; connecting a base die to the base structure in a block 1704; connecting a supporting die over the base die by conductive balls to the contact pads on two sides of the base die in a block 1706; encapsulating the contact pads, the base die, the supporting die, and the conductive balls in a block 1708; and removing the base structure in a block 1710.

The resulting method, process, apparatus, device, product, and/or system is straightforward, cost-effective, uncomplicated, highly versatile and effective, can be surprisingly and unobviously implemented by adapting known technologies, and are thus readily suited for efficiently and economically manufacturing semiconductor packaging systems fully compatible with conventional manufacturing processes and technologies.

Another important aspect of the present invention is that it valuably supports and services the historical trend of reducing costs, simplifying systems, and increasing performance.

These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
attaching contact pads to a base structure;
connecting a base die to the base structure;
connecting a supporting die over the base die by conductive balls to the contact pads on two sides of the base die;
encapsulating the contact pads, the base die, the supporting die, and the conductive balls; and
removing the base structure.

2. The method as claimed in claim 1 further comprising:
attaching further contact pads to the base structure;
attaching a top device to the supporting die; and
connecting the top device to the further contact pads by bonding wires on two sides of the base die.

3. The method as claimed in claim 1 further comprising:
patterning the base structure; and
forming the contact pads in the patterned base structure to form bumped contact pads to contain the conductive balls.

4. The method as claimed in claim 1 further comprising:
attaching a top device to the supporting die; and
encapsulating includes encapsulating the top device with a top of the top device exposed.

5. The method as claimed in claim 1 further comprising:
attaching a top device to the supporting die; and
attaching a further die to a top of the top device.

6. A method of manufacture of an integrated circuit packaging system comprising:
attaching contact pads to a base structure;
connecting a base die to the base structure;
connecting a supporting die over the base die by conductive balls to the contact pads on two sides of the base die, the supporting die connected by further conductive balls to the base die or the base die connected by the further conductive balls to the base structure;
encapsulating the contact pads, the base die, the further conductive balls, the supporting die, and the conductive balls; and
removing the base structure.

7. The method as claimed in claim 6 further comprising:
attaching further contact pads to the base structure;
attaching a top device to the supporting die;
connecting a further die to the top device by top conductive balls; and
connecting the top device to the further contact pads by bonding wires on two sides of the supporting die.

8. The method as claimed in claim 6 further comprising:
patterning the base structure;
forming the contact pads in the patterned base structure to form bumped contact pads to contain the conductive balls; and
forming a pad in the patterned base structure to form a die attach pad to contain the base die.

9. The method as claimed in claim 6 further comprising:
attaching a top device to the supporting die;
connecting a top of the top device to the contact pads by bonding wires; and
encapsulating includes encapsulating the bonding wires and the top device with a top of the top device exposed.

10. The method as claimed in claim 6 further comprising:
attaching a top device to the supporting die;
connecting a top of the top device to the contact pads by bonding wires;
encapsulating includes encapsulating the bonding wires and the top device with a top of the top device exposed; and
attaching a further die to the exposed top of the top device.

11. An integrated circuit packaging system comprising:
contact pads;
a base die connected to the contact pads;
a supporting die supported over the base die by conductive balls to the contact pads on two sides of the base die; and
an encapsulant encapsulating the contact pads, the base die, the supporting die, and the conductive balls.

12. The system as claimed in claim 11 further comprising:
further contact pads; and
a top device attached to the supporting die, the top device connected to the further contact pads by bonding wires on two sides of the base die.

13. The system as claimed in claim 11 further comprising:
bumped contact pads for containing the conductive balls.

14. The system as claimed in claim 11 further comprising:
a top device attached to the supporting die; and
an encapsulant encapsulating the top device with a top of the top device exposed.

15. The system as claimed in claim 11 further comprising:
a top device attached to the supporting die; and
a further die attached to a top of the top device.

16. The system as claimed in claim 11 wherein:
the supporting die is connected by further conductive balls to the base die or the base die is connected by the further conductive balls to the base structure; and
encapsulating the further conductive balls.

17. The system as claimed in claim 16 further comprising:
further contact pads;
a top device attached to the supporting die;
a further die connected to the top device by top conductive balls; and
the top device connected to the further contact pads by bonding wires on two sides of the base die.

18. The system as claimed in claim 16 further comprising:
bumped contact pads to contain the conductive balls; and
a bumped die attach pad to contain the base die.

19. The system as claimed in claim 16 further comprising:
a top device attached to the supporting die;
a top of the top device connected to the contact pads by bonding wires; and
an encapsulant encapsulating the bonding wires and the top device with a top of the top device exposed.

20. The method as claimed in claim 16 further comprising:
a top device attached to the supporting die;
a top of the top device connected to the contact pads by bonding wires;
an encapsulant encapsulating the bonding wires and the top device with a top of the top device exposed; and
a further die attached to the exposed top of the top device.
